(19) United States
(12) Patent Application Publication
(10) Pub. No.: US 2026/0343815 A1
(43) Pub. Date: Oct. 29, 2026

(54) DATA CENTER COOLING

(71) Applicant: Schlumberger Technology Corporation, Sugar Land, TX (US)

(72) Inventors: Andrew Clarke, Cambridge (GB); John Morrison Whyte, Cambridge (GB); Carlos Abad, Sugar Land, TX (US)

(21) Appl. No.: 19/660,479

(22) Filed: Apr. 28, 2026

(30) Foreign Application Priority Data
Apr. 28, 2025 (GB) 2506416.3
Dec. 4, 2025 (GB) 2520735.8

(51) Int. Cl. H05K 7/20

(52) U.S. Cl. CPC H05K 7/20272; H05K 7/20263; H05K 7/2079

(57) ABSTRACT

A data center cooling system, for collecting heat at multiple input locations and carrying it to a heat exchanger for discharging the heat, circulates a coolant liquid in which supramolecular aggregates, which may be worm-like viscoelastic surfactant micelles, reduce drag in pipework, where the liquid is in a state of inertial turbulence. The supramolecular aggregates are disrupted adjacent the inlet to the heat exchanger or within the heat exchanger. The heat exchanger may apply more shear to the coolant than the pipework leading to the heat exchanger, so as to disrupt the supramolecular aggregates while the coolant flows through the heat exchanger.

### CROSS REFERENCE TO RELATED APPLICATIONS

This application claims the benefit of GB Patent Application No.: 2520735.8, entitled “Data Center Cooling”, filed Dec. 4, 2025, the disclosure of which is hereby incorporated herein by reference. This application also claims priority to GB Patent Application No.: 2506416.3, which was filed on Apr. 28, 2025, which is likewise incorporated herein by reference in its entirety.

### FIELD

This disclosure relates to cooling of electronic components and circuit boards carrying electronic components as used in large numbers in data centers.

### BACKGROUND

A data center typically contains numerous racks of computing equipment containing circuit boards on which there are electronic components which produce heat as they operate. It is conventional that a data center has a combination of systems for cooling these components during operation. One system may contain a circulating coolant liquid which is heated at multiple locations at or close to the racks where the heat is generated and then flows through pipework to a heat exchanger where the heat energy is discharged to another cooling system which carries the heat energy elsewhere, for example, to the environment outside the building.

The coolant used in such a system may be an aqueous solution, such as an aqueous solution containing 25% by weight of a glycol. The amount of coolant liquid in such a system may be large. A typical system may have heated solution arriving at the heat exchanger where it will be cooled at a rate of 10 cubic meters (about 2600 US gallons) per minute. A pipe of 35 cm (14 inch) diameter may be used in a typical system to carry the fluid as it arrives at the heat exchanger.

It is of course well known that Newtonian fluids such as water can undergo either laminar flow or turbulent flow which may be referred to as inertial turbulence. It is also well known that the transfer of heat into or out of a flowing liquid is much more efficient if the liquid is in a state of turbulence rather than laminar flow. Turbulent flow occurs at higher flow speeds than laminar flow. Flow conditions for laminar and turbulent flow are often expressed by Reynolds number which is a ratio of inertial to viscous forces within a fluid. Reynolds number (Re) is given by the formula:

$$R e = \frac{ρ UL}{μ}$$

where ρ is density of the liquid, U is flow velocity, u is viscosity and L is a so-called characteristic length related to the size and shape of the flow path. For flow through a round tube, the characteristic length L is the internal diameter D of the tube and the above formula can be rewritten as

$$R e = \frac{4 ρ Q}{π μ D}$$

where Q is the volumetric flow rate and the cross section for flow within the tube is ¼πD². Reynolds number has no dimensions because it is a ratio. At Reynolds number above about 2000, there is inertial turbulent flow.

With a flow rate and pipe size as mentioned above for a typical data center, the flow of coolant liquid is turbulent. Within the heat exchanger where the heat energy is transferred to another system which carries it outside the building, turbulence is advantageous because it enhances heat transfer. However, within the pipework to and from the heat exchanger, which may be lengthy, turbulence has the disadvantage that it increases the drag (friction between the pipe wall and the flowing liquid) and dissipates energy which has to be supplied by the pumping system. The amount of energy needed for pumping the coolant around its circuit can be a significant proportion of the energy consumed by a data center.

It is well known that drag on liquid in a state of turbulent flow through piping can be reduced by adding a drag reducing agent, which is often a long-chain polymer. This is believed to reduce turbulence in a peripheral layer in contact with the pipe wall and thereby reduce the drag which is the friction between the pipe wall and the liquid flowing over it. It is also known that a viscoelastic surfactant which is capable of forming supramolecular aggregates, such as linear tubular micelles (usually referred to as worm-like micelles) in aqueous solution can act as a drag-reducing agent in a similar manner. Worm-like micelles are a form of supramolecular aggregates which can be formed by spontaneous association of surfactant molecules. Others are branched tubular micelles and bicontinuous networks.

Drag reduction can be quantified as a percentage of the original pressure drop between two points in a pipe (or other shape of duct) carrying liquid flow. The pressure drop between the two points carrying a control liquid is measured as ΔPw. The pressure drop between the same two points after adding the drag reducing agent to the liquid is measured as ΔPf. The percentage drag reduction is given by the formula:

$$\% DR = \frac{Δ P w - Δ P f}{Δ P w} \times 100 \%$$

### SUMMARY

This summary is provided to introduce concepts that will be further elaborated and described below in the detailed description. This summary is not intended to identify key or essential features of the claimed subject matter, nor is it intended to be used as an aid in limiting the scope of the claimed subject matter.

Supramolecular aggregates are structures containing a large number of molecules held together by attractions between molecules but not by covalent bonds. These structures may have a length or area which is much more than any dimension of the component molecules. Supramolecular aggregates formed by viscoelastic surfactants may be tubular micelles. These tubular micelles may have linear or branched structure or be a network of tubes connected at multiple points. Linear tubular micelles are commonly referred to as worm-like micelles. Supramolecular aggregates formed by surfactants can also take the form of a biphasic network containing micelles which are more polar at their exterior than their interior and other micelles which are more polar at their interior than their exterior.

If a solution containing a polymer as drag reducing agent is subjected to shear, the molecules of the drag reducing agent can be broken by breakage of covalent bonds in the polymer and the ability to reduce drag is permanently degraded. When a drag reducing agent is a substance which forms supramolecular aggregates such as worm-like micelles, the connection between molecules of the compound is attraction between molecules, rather than covalent bonds as mentioned above with the consequence that such aggregates can spontaneously reform after disruption and resume their action of reducing drag.

In a first aspect, the present disclosure provides a method of transferring heat within a data center, comprising pumping a coolant liquid through a system of pipework from one or more heat input locations receiving heat from electronic components to a heat exchanger transferring heat to another system, wherein
the coolant liquid contains a compound which is able to form supramolecular aggregates which can reduce drag (which is resistance to flow at the walls of the pipework),
during flow through at least part of the travel from the heat input locations to the heat exchanger, the coolant liquid, the pipework dimensions and the speed of flow are such that the flowing coolant is in a state of turbulence and the presence of supramolecular aggregates reduces drag, and
during flow through at least part of the heat exchanger, the coolant flow is in a state of turbulence but in consequence of temporary disruption of the supramolecular aggregates, the said compound gives less reduction of drag.

The method will, in many instances, also include returning the coolant from the heat exchanger through another system of pipework to the heat input locations and during at least part of this return travel the pipework dimensions and the speed of flow may be such that the flowing coolant is in a state of turbulence and the formation of worm-like micelles or other supramolecular aggregates again reduces drag.

A second aspect of the present disclosure provides a data center heat transfer system comprising
a heat exchanger comprising one or more internal flow paths from which heat transfers to another system,
pipework, external to the heat exchanger, configured to provide a flow path for coolant liquid from one or more heat inputs receiving heat from computing equipment to the heat exchanger,
a coolant liquid, and
at least one pump for propelling the liquid through the pipework to the heat exchanger, wherein
the coolant liquid contains a compound able to spontaneously form supramolecular aggregates,
in at least part of the pipework, the coolant liquid, the pipework dimensions and the pumping rate provide turbulent flow in which supramolecular aggregates reduce drag, and
in at least part of the internal flow paths of the heat exchanger, there is temporary disruption of the aggregates and less reduction of drag.

In the method and system stated above, the formation of supramolecular aggregates such as worm-like micelles can reduce drag on the coolant liquid as it flows along a pipe and thereby reduce the pumping power required to circulate the liquid. However, while reduction of drag in pipework external to the heat exchanger is useful because it reduces the required pumping power, it is counter-productive in a heat exchanger where turbulence carries hot liquid to the walls through which the heat is required to pass. Disrupting at least some of the aggregates as they enter the heat exchanger or within the heat exchanger will mitigate or avoid the reduction of efficiency by intact aggregates within the heat exchanger.

Disrupting supramolecular aggregates and thereby reducing the concentration of supramolecular aggregates within at least part of the heat exchanger may be done in several ways. One possibility is to configure at least part of the heat exchanger with a cross-section for liquid flow which is less than the cross section for flow in the pipework leading to the heat exchanger, thereby forcing an increase in flow velocity to a point at which the turbulence becomes sufficiently vigorous to disrupt the micelles. Another possibility is that internal flow paths in the heat exchanger are shaped to subject the flow to greater shear than in the pipework external to the heat exchanger.

Provided the time for supramolecular aggregates to reform after disruption is sufficiently long, it is possible to disrupt the aggregates before they enter the heat exchanger. One possibility for this is to use a pump which subjects the liquid flowing through the pump to shear and position it close to the inlet to the heat exchanger so that the pump disrupts the supramolecular aggregates during passage through the pump shortly before they enter the heat exchanger, and re-formation of the aggregates is incomplete during travel through at least part of the heat exchanger. Another possibility is to include, in the flow path at or close to the entrance to the heat exchanger, a structure which is not a pump, but which compels the flowing coolant liquid to undergo extensional flow.

A number of chemical compounds spontaneously form aggregates which are worm-like micelles when the compounds are in aqueous solution. Many of these are viscoelastic surfactants and a number of possibilities are set out in T. Saeki, “Flow properties and heat transfer of drag reducing surfactant solutions” which is chapter 18 of “Developments in Heat Transfer” edited by D. M. A. D. S. Bernardes, published by InTechOpen, 2011. One possibility mentioned there is cetyl-trimethyl-ammonium chloride in a solution also containing sodium salicylate. Another possibility is stearyl-trimethyl-ammonium chloride which is effective in reducing drag at temperatures up to and above 100 °C. A suitable concentration of a compound to form worm-like micelles may be 10 μm/litre or less, possibly from 1 to 10 or 1 to 5 μm/litre. Such a compound may have a molecular weight not greater than 1000 Daltons.

It has been reported in co-owned U.S. Pat. No. 9,034,802, which was concerned with oilfield uses such as hydraulic fracturing, that polymers with ionic groups can act as “enhancers” for worm-like micelles, increasing the amount of stress required to break up the micelles. Using a combination of a viscoelastic surfactant and a polymer as enhancer in order to form supramolecular aggregates in accordance with the present disclosure may improve drag reduction at the high flow rates needed for cooling of a data center while still allowing disruption of the supramolecular aggregates at the heat exchanger.

A further aspect of the present invention is a data center heat transfer system comprising
pipework configured to provide a flow path for heated liquid from one or more heat inputs receiving heat from computing equipment to a heat exchanger for transferring heat to another system,
a coolant liquid which contains (i) a compound able to spontaneously form supramolecular aggregates, and (ii) a polymer which has a molecular weight not greater than 20 kiloDaltons and which has ionic groups in the polymer chain or in side chains attached to the polymer chain, and
at least one pump for propelling the liquid through the pipework to the heat exchanger.

Then in at least part of the travel from the heat input locations to the heat exchanger, the coolant liquid, the pipework dimensions and the pumping rate are such as to give coolant flow which is in a state of turbulence while the formation of supramolecular aggregates reduces resistance to flow.

### BRIEF DESCRIPTION OF THE DRAWINGS

FIG. 1 is a schematic cross section of a data center building.

FIG. 2 is a schematic cross section of a server on line Y-Y of FIG. 3.

FIG. 3 is a cross section on line X-X of FIG. 2.

FIG. 4 is a schematic cross section of another data center building.

FIG. 5 is a cross section of a portion of pipework configured to cause extensional flow of liquid entering the heat exchanger.

FIG. 6 is a cross section of the same portion of pipework on the line J-J of FIG. 5.

FIG. 7 is a cross section on the line K-K of FIG. 6.

FIG. 8 is a cross section of a portion of pipework also configured to cause extensional flow of liquid entering the heat exchanger.

FIG. 9 is a cross section of a coolant bath, a computing device immersed in the bath and an associated heat exchanger.

FIG. 10 is a schematic cross section of a further data center building.

FIG. 11 is a schematic cross section of a heat exchanger.

FIG. 12 is a schematic cross-section of another heat exchanger.

FIG. 13 is a cross section on line Z-Z of FIG. 12.

FIG. 14 is a schematic cross section of a further heat exchanger.

FIG. 15 shows a portion of twisted tape.

### DETAILED DESCRIPTION

This detailed description shows various embodiments of the present disclosure and possibilities which may be used. These are given as examples and do not limit this disclosure as defined by the claims. It should be appreciated that features or possibilities described in combination may, where it is practical to do so, be used separately. Also, features or possibilities described in any embodiment may be used in any other embodiment, in so far as it is possible to do so.

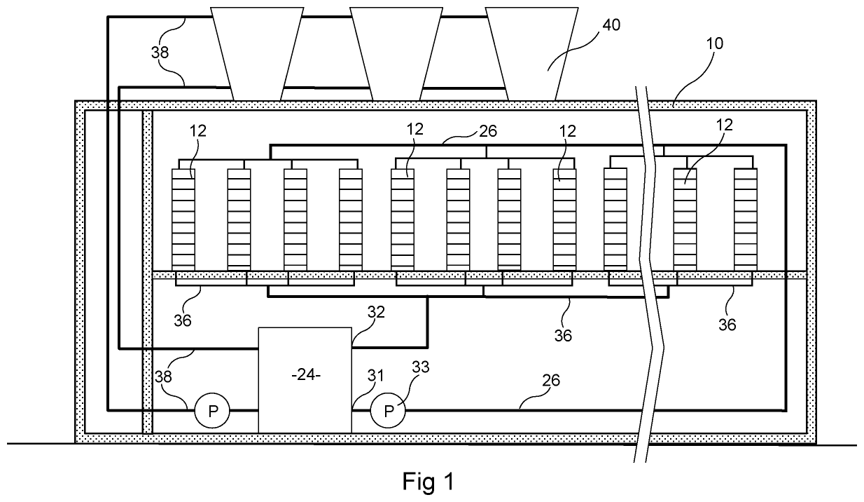

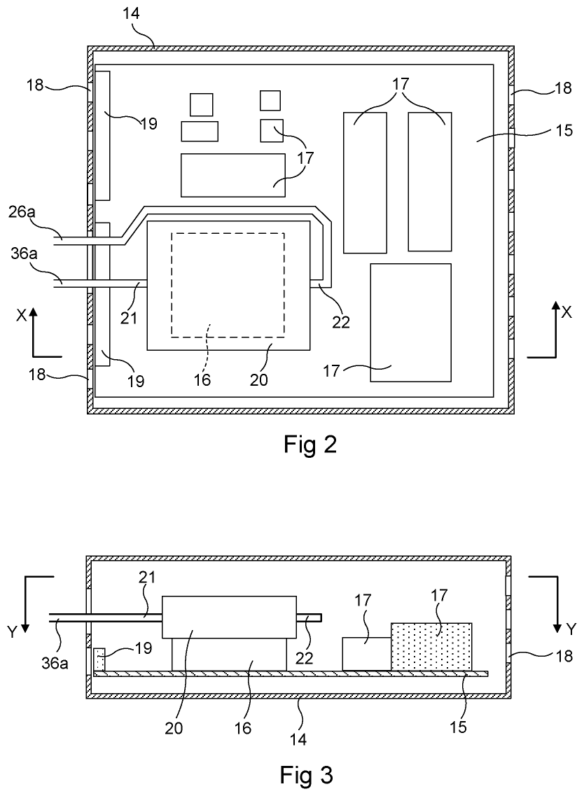

FIG. 1 is a schematic cross section of a two-storey building which is a data center 10. The upper storey of the building contains a large number of racks 12 each of which contains a number of computing devices, such as servers. One such computing device is shown schematically by FIGS. 2 and 3. It has an outer case 14 inside which is a printed circuit board 15 to which various electronic components are soldered. In this example, the components include a CPU 16 as well as other components 17. The case 14 has openings 18 at opposite ends to allow air to flow through and also to allow electrical connections to connector blocks 19.

In operation the CPU 16 emits heat. Cooling of the CPU is provided by a so-called cold plate 20 which is a hollow vessel made of metal such as copper or aluminium and mounted in direct contact with the CPU 16 so as to allow heat emitted by the CPU to be conducted into the vessel 20. Coolant liquid is supplied to the vessel 20 at inlet 21 and leaves at outlet 22. Many or all of the numerous other computing devices in the racks 12 also have cold plates 20 in them, to collect heat emitted from CPUs, GPUs and other electronic components which emit heat during operation.

The data center has a cooling system embodying the present disclosure. This system includes a large heat exchanger 24. A branching system of pipework 26 connects the outlets 22 of the cold plates 20 to a pump 33 located close to the heat exchanger 24. This pump 33 is connected by a further pipe of similar diameter to the inlet of the large heat exchanger 24. The outlet 32 of the heat exchanger 24 is connected to another branching system of pipework 36 for return flow of coolant to the cold plates 20. The large heat exchanger 24 transfers heat energy from the flow arriving along the pipework 26 to water flowing in another flow circuit 38 which carries the heat to cooling towers 40 on the roof of the data center 10.

The inlet 21 and outlet 22 of each cold plate 20 have small diameter pipes 26a and 36a connected to them. These are part of the branching pipework systems 26 and 36. The inlet 31 and the outlet 32 of the heat exchanger 24 and the pipes connected to them are of large diameter. The branching systems of pipework 26, 36 may include pipes of intermediate diameters. These branching systems may also include components other than pipes. For example, the system 36 which carries return flow from the heat exchanger 24 to the cold plates 20 may include flow controlling valves and/or auxiliary pumps to control the proportions of flow in each of a number of pipes leading from a branch point.

The heat exchanger 24, the pipework systems 26, 36 and the cold plates 20 are filled with a coolant liquid which may be an aqueous solution of a glycol. The pump 33 propels the coolant around the whole system so that heated coolant from the outlets 22 of the cold plates 20 is carried through the pipework system 26 to the pump 33 which propels the flow into the inlet 31 of the heat exchanger and after passing through the heat exchanger 24 return flow of cooled liquid is carried through the pipework 36 to the inlets 21 of the cold plates 20. In the larger diameter pipes of the pipework systems 26, 36 and in particular in the large pipes connected to the pump 33 and outlet 32 of the heat exchanger the coolant may travel at a sufficiently high flow rate that the flow is in a state of inertial turbulence, with a Reynolds number over 2000 (and possibly much more, such as over 20,000).

In accordance with the present disclosure the coolant liquid circulating from the cold plates to the heat exchanger 24 and back again contains a small percentage of a viscoelastic surfactant able to form supramolecular aggregates. These may be tubular micelles and may be linear tubular micelles which are usually referred to as worm-like micelles. In at least the larger parts of the pipework 26, these micelles modify the interaction between the periphery of the coolant flow and the pipe walls in a way which reduces the drag on the flowing liquid and so enhances the speed of flow or enables use of a less powerful pump than would be required in the absence of drag reduction by the worm-like micelles. However, while this is beneficial in the pipework systems 26, 36 it would reduce thermal contact with surfaces in the heat exchanger and so would be disadvantageous there.

The pump 33 which propels the coolant flow also subjects the coolant liquid to shear, as many pumps do, and because the pump is positioned adjacent to the inlet 31 of the heat exchanger 24 (i.e. slightly upstream from the inlet 31, but close to it) the worm-like micelles are broken up by the shear force on the liquid, just before that liquid enters the heat exchanger 24 through its inlet 31.

It is desirable that the outlet of pump 33 is close to the inlet 31 of the heat exchanger. It may for instance be no more than 2 meters from the heat exchanger inlet 31, possibly no more than 1 meter from the inlet 31.

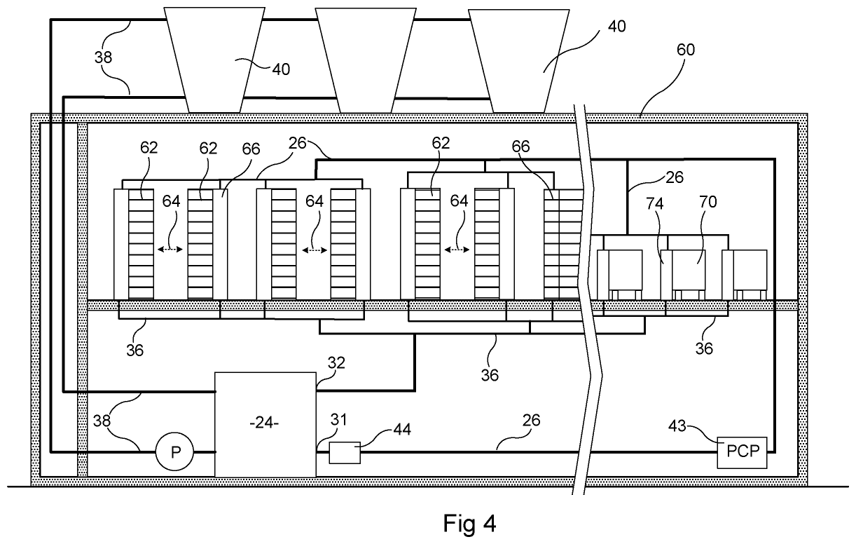

FIG. 4 is a schematic view of a data center 60 which differs from that of FIG. 1. This has a different system for pumping the coolant and disrupting supramolecular aggregates such as micelles. It also differs in that it uses other methods of collecting heat energy from electronic components which generate heat when they operate. It should be appreciated that the methods of collecting heat energy shown in this FIG. 4 could be used with the cooling system of FIG. 1 and that the collection of heat energy shown in FIG. 1 could be used with the cooling system of this FIG. 4.

The cooling system in this data center has a heat exchanger 24 and pipework systems 26, 36 similar to those shown in FIG. 1. The coolant is a solution of a compound which spontaneously forms worm-like micelles. However, the circulation of the coolant is brought about by a progressive cavity pump 43 which will not apply much shear to the flowing liquid. This is located at a substantial distance from the heat exchanger 24 and the worm-like micelles in the coolant reduce drag as the coolant flows from the pump 43 towards the heat exchanger 24. Just before the coolant arrives at the inlet 31 of the heat exchanger 24, it passes through a structure 44, incorporated in the pipework 26, which compels the liquid to undergo extensional flow, disrupting the worm-like micelles as they enter the heat exchanger 24 through its inlet 31.

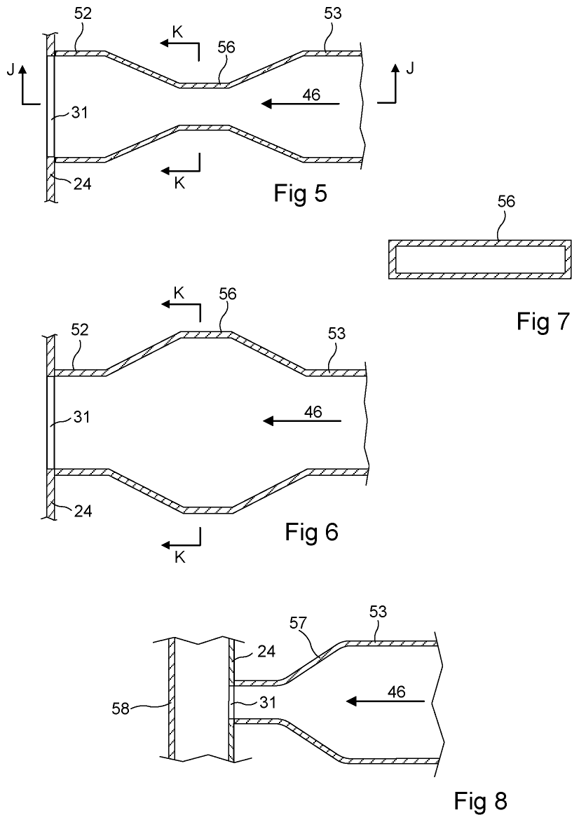

One possibility for such a structure is shown in FIGS. 5 to 7. The flow direction is indicated by arrow 46. The portions of the structure indicated as 52 and 53 are cylindrical and have the diameter of the pipework 26 approaching the inlet 31. Between portions 52 and 53, the portion 56 has a rectangular cross section shown by FIG. 7 and this has a cross-sectional area for flow which is less than the cross-sectional area of the cylindrical portion 53. This compels the incoming flow towards the heat exchanger to accelerate and therefore undergo extensional flow which disrupts the worm-like micelles just before the flow arrives at the inlet 31 of the heat exchanger 24.

It is desirable that the structure 44, which induces extensional flow is positioned close to the inlet 31 of the heat exchanger. It may for instance be no more than 2 meters from the heat exchanger inlet 31, possibly no more than 1 meter from the inlet 31.

Another possibility for structure to cause extensional flow is shown in FIG. 8. As the pipe 53 approaches the inlet 31 of the heat exchanger 24 it includes a conical portion 57 which accelerates the flow and forms it into a jet. This jet is directed into the heat exchanger 24 and strikes an internal wall 58 within the heat exchanger, thereby creating further extensional flow which disrupts the worm-like micelles.

In part of the upper storey of the building 60 there are racks 62 each of which contains a number of computing devices. These have an outer case 14 inside which there is a printed circuit board to which electronic components 16, 17 are soldered. This is similar to the arrangement shown by FIGS. 2 and 3 except that cold plates are not used.

The racks 12 are arranged in pairs facing each other. To cool the electronic components 16, 17 air is blown into the aisle between each pair of racks 62, for the air to flow into the computing devices in the racks as indicated at 64. At the other side of each rack 62 there is a so-called rear-door heat exchanger 66 which transfers heat energy from the air to a flow of coolant liquid.

The branching pipework systems 26, 36 are connected to the rear door heat exchangers 66 so that heat energy carried by the air flow is transferred to the coolant liquid passing through the heat exchangers 66. It is also possible to locate heat exchangers which transfer heat from the airflow to the coolant liquid at other positions, such as above the racks 62.

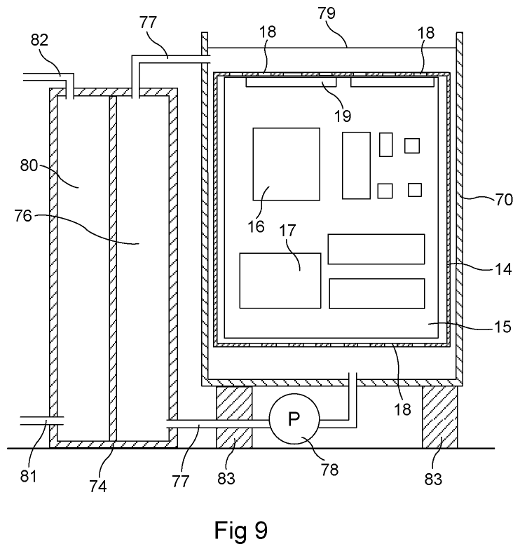

In another part of the upper storey of the building 60, computing devices are cooled by immersion in baths 70 of a non-conductive liquid, referred to as dielectric fluid. The position of the baths 70 is indicated in FIG. 4 and one bath is shown by FIG. 9. Each bath 70 is raised on supports 83. Alongside the bath there is a heat exchanger 74 with a chamber 76 connected to the bath 70 by pipes 77 with a pump 78 to circulate dielectric fluid from the bath through the chamber 76. The surface of the dielectric fluid in the bath 70 is indicated at 79. Computing devices with cases 14 are fitted into the bath from above and the dielectric fluid flows upwardly into and through the computing devices. It enters and leaves through the holes 18 in the cases 14.

The inlet 81 of the other chamber 80 of the heat exchanger 74 is connected to the pipework system 36 and the outlet 82 is connected to the pipe work system 26 and so coolant circulated by the pump 43 flows through the chamber 80 of the heat exchanger 74 to collect heat energy from the dielectric fluid.

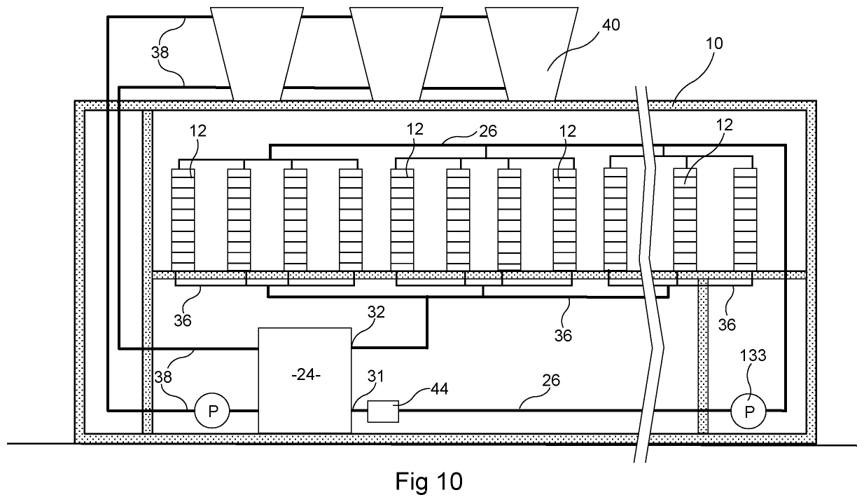

FIG. 10 shows a further data center most of which is the same as the data center shown by FIG. 1. It has a heat exchanger 24 and a pump for circulating coolant. The pump is located a long way from the heat exchanger 24. The coolant liquid includes a viscoelastic surfactant in solution so as to enable worm-like micelles to form spontaneously. As a result, the flowing coolant forms worm-like micelles in the pipework systems 26, 36 as happened with the data center shown in FIG. 1. Formation of the micelles takes time and so they are not completely formed in the coolant liquid as it leaves the pump. The micelles continue to form spontaneously during flow along the pipework 26 which may be very long. When the flow arrives at the heat exchanger, the micelles are disrupted by a structure 44 as described above with reference to FIGS. 5 to 7 or FIG. 8 which is included in the pipework 26 close to the inlet 31 of the heat exchanger

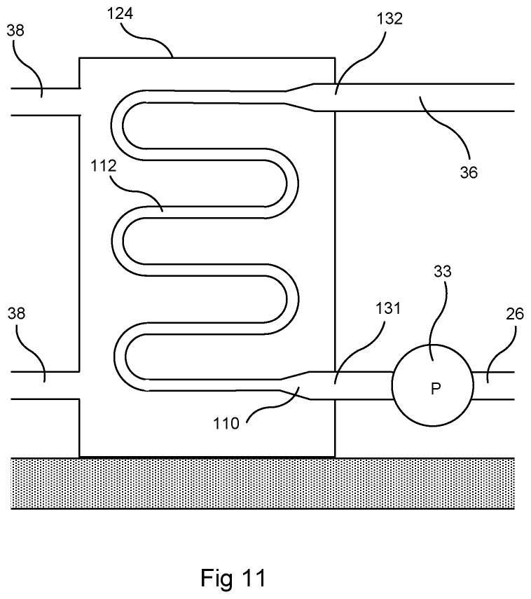

It is possible that disruption of worm-like micelles takes place inside the heat exchanger. FIG. 11 shows one possibility for this. FIG. 11 shows, diagrammatically, the interior of a heat exchanger 124 in cross section. This may be located in a data center such as the data center of FIG. 10 wherein the pump for circulating the coolant is located at a distance from the heat exchanger. Flow entering the heat exchanger 124 through its inlet 131 passes through a conical section 110 and then continues through a sinusoidal internal pipe 112. Within the heat exchanger, the space around the pipe 112 contains the water which is circulated to and from the roof through the pipework 38.

The internal pipe 112 has smaller diameter than the pipework 26, 36 leading to and from the heat exchanger 124. Consequently, the velocity of flow in this internal pipe 112 is faster than the velocity of flow in the pipework 26, 36 and so turbulence in the pipe 112 is more forceful than in the pipework 26 and 36. The composition of the coolant liquid and the flow velocities are selected so that there are worm-like micelles providing drag reduction in the pipework 26, 36 but these are disrupted in the smaller diameter pipe 112 where the faster flow speed and consequent more forceful turbulence breaks up the worm-like micelles and prevents them from reforming. Thus, there is no layer of non-turbulent liquid closely adjacent to the interior of the pipe 112 hindering the transfer of heat energy from the coolant arriving along pipework 26, through the wall of pipe 112 to the surrounding water of the flow circuit 38.

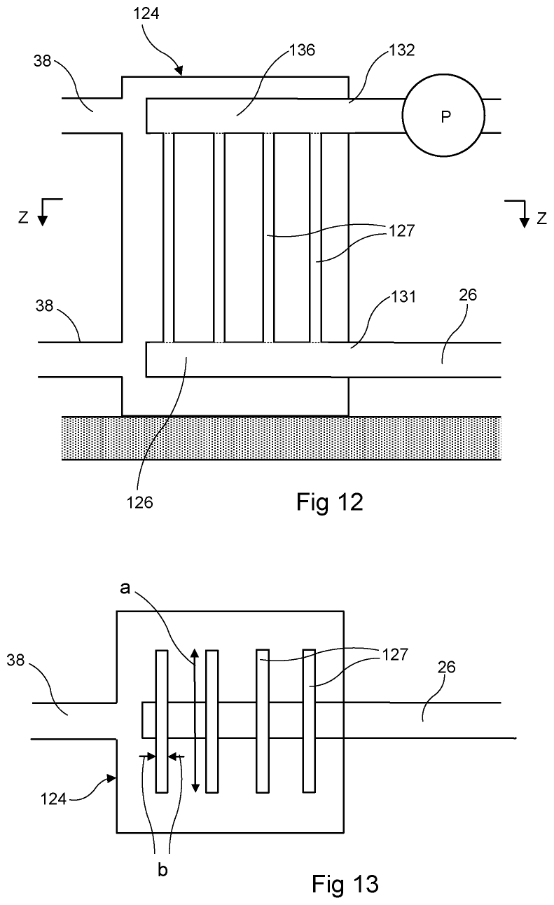

FIGS. 12 and 13 show another possibility for the heat exchanger 124. At the inlet 131, the pipework 26 is connected to an inlet manifold 126 which is connected by a plurality of ducts 127 to an outlet manifold which carries the flow to the outlet 132 of the heat exchanger and so to the return pipework 36. Each duct 127 has a narrow rectangular cross section as shown by FIG. 13. These have a width Wa which may be the same as the diameter of the pipework 26 and the inlet manifold 126 but the transverse width Wb is much less. The number of ducts 127 and the dimensions Wa and Wb may be chosen such that the total cross sectional area of the ducts 127 is approximately the same in the cross section of the pipework 26 and inlet manifold 126, so that the velocity of flow in the ducts 127 is the same as in the pipework 26, but the shear applied to liquid flowing in the ducts 127 is greater than in the pipework 26, with the consequence that worm-like micelles are disrupted in the ducts 127 by this greater shear. The number and dimensions of the ducts 127 may also be chosen such that the total cross section for flow is smaller than that of the pipework 26, thus further increasing the shear within the flowing liquid.

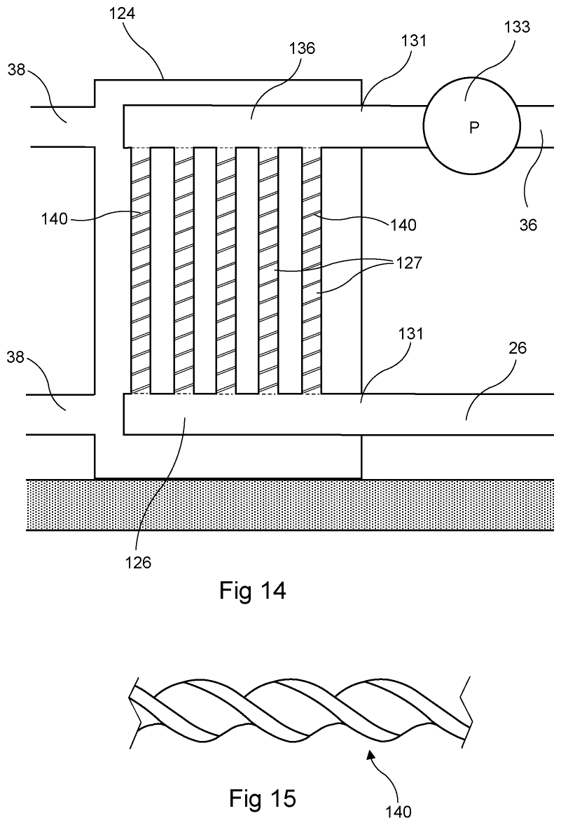

FIGS. 14 and 15 show a further possibility. The inlet and outlet manifolds are connected by circular pipes 140 which may have a total cross-sectional area which is approximately equal to that of the pipework 26. Inside each pipe 140 there is a so-called twisted tape coiled into a helix which projects inwardly from the wall of the pipe 140.

A twisted tape is a metal strip twisted around its center line so that the edges of the twisted strip become a helix around that center line. A portion of such a twisted tape is shown in FIG. 15. The use of twisted tapes in heat exchangers has been described by Liu and Sakr in “A comprehensive review on passive heat transfer enhancements in pipe exchangers”, Renewable and Sustainable Energy Reviews (2013), Vol 19, Pages 64-81.

In the pipes 140 of the heat exchanger shown by FIG. 14, the twisted tape will force flow adjacent to the pipe wall to divert, thereby applying shear to the flowing liquid and disrupting worm-like micelles in the flow.

As mentioned above, the coolant liquid may include a polymer as an “enhancer” which is able to extend the range of flow speeds within which drag reduction occurs. Polymeric drag reduction enhancers for combination with cationic and zwitterionic drag reducing surfactants include polycondensation product of sodium naphthalene sulfonate with formaldehyde, having a molecular weight of about 2000-3000 Daltons commercially available from Geo Specialty Chemicals as Daxad® 17 which is in solid form or in 50% aqueous solution as Daxad 16L. Polycondensation products of sodium naphthalene sulfonate with formaldehyde, having a molecular weight of about 10000-20000 Daltons may also be used. Further possibilities are copolymers obtained by formaldehyde or melamine condensation of naphthalene sulfonate with other monomers such as phenol, alkylated phenols or bisphenols, polymers of other monomers containing sulfonate groups, low molecular weight negatively charged polysaccharides such as carboxymethyl cellulose, and methacrylate polymers and copolymers.

Polymeric drag reduction enhancers for use with anionic surfactants which can form worm-like micelles may be cationic low molecular weight polymers or copolymers. Examples are polymers obtained by radical polymerization of dimethylamino ethyl methacrylate (DMAEMA), 2-(methacryloyloxy)-ethyltrimethylammonium chloride (MADQUAT), methacrylamidopropyl trimethyl ammonium chloride (MAPTAC), or diallyldimethylammonium chloride (DADMAC). Other suitable polymers that can perform as polymeric drag reduction enhancers in combination with anionic drag reducing surfactants are cationic polysaccharides such as cationic guar or cationic starch.

In some embodiments of this disclosure, the coolant liquid which circulates through the pipework 26, 36 is an emulsion or suspension in which the disperse phase is able to melt and to freeze at temperatures which are above the temperature of cooled liquid flowing into the pipework 36 from the heat exchanger 24 or 124 but below a maximum operating temperature for the electronic components which are emitting heat. Such a disperse phase will increase the heat carrying capacity of the circulating coolant liquid because melting of the disperse phase will require the latent heat of fusion of that phase in addition to heat to raise the temperature of the liquid.

As an illustration of this, if a circulating liquid is water and a unit mass of water with specific heat capacity cₚ^{water} is heated from temperature T₁ which is 25 °C to temperature T₂ which is 40 °C the enthalpy change is:

$$Δ {E}^{w o t e r} = {c}_{p}^{w o t e r} ( {T}_{2} - {T}_{1} )$$

A hypothetical circulating coolant liquid is an emulsion with a continuous phase which is water and a disperse phase which is nonadecane melting to an oil at 32 °C. If unit mass of an emulsion containing proportion φ of the hydrocarbon is heated over the same temperature range, and the melting point of the hydrocarbon is between T₁ and T₂, the enthalpy change is:

$$Δ {E}^{p c m} = ϕ ( {L}^{oil} + {c}_{p}^{oil} ( {T}_{2} - {T}_{1} ) ) + ( 1 - ϕ ) {c}_{p}^{w a t e r} ( {T}_{2} - {T}_{1} )$$

where L^{oil} is the latent heat of fusion of the hydrocarbon and for simplicity it is assumed that the specific heat of the hydrocarbon is the same for its frozen and liquid forms. In the case of an emulsion containing 30 vol % of nonadecane as the disperse phase in water as continuous phase, and with a temperature rise of 15° between T₁=25 °C and T₂=40 °C spanning the 32 °C melting temperature of the nonadecane, the calculated enthalpy change of the emulsion is approximately twice that of water alone.

One possibility for such a disperse phase comprises small particles which melt and freeze during circulation, with the individual particles encapsulated within a polymer shell. Such encapsulated particles can provide a dispersion with very good stability.

Various embodiments of this disclosure have been set out above. These are intended to assist understanding of this disclosure, but not to limit it in any way. It should be appreciated that any features or possibilities described in combination may, where it is practical to do so, be used individually. Also, features or possibilities mentioned in the following claims or described in any embodiment may be used in any other embodiment, in so far as it is practical to do so and where two or more of the following claims are dependent on the same preceding claim, the reader should understand that the present disclosure includes any possible combination of any two or more or all of those dependent claims with each other and also with that preceding claim.

1. A method of transferring heat within a data center, comprising pumping a coolant liquid through a system of pipework from one or more heat input locations receiving heat from electronic components to a heat exchanger from which heat transfers to another system, wherein:
the coolant liquid contains a compound which is able to form supramolecular aggregates in the coolant liquid;
in at least part of the pipework between the heat input locations and the heat exchanger, the coolant liquid, the pipework dimensions and the speed of flow are such that the flowing coolant is in a state of turbulence and the formation of supramolecular aggregates reduces drag; and
the method comprises temporarily disrupting the supramolecular aggregates during flow into or within the heat exchanger, so that during flow of coolant liquid through at least part of the internal flow paths within the heat exchanger, there is less reduction of drag than in the said part of the pipework.

2. The method of claim 1, wherein the said part of the internal flow paths subjects the flow therethrough to greater shear than in the said part of the pipework between the heat input locations and the heat exchanger.

3. The method of claim 1, wherein the flow speed in the said part of the internal flow paths is greater than the flow speed in the said part of the pipework between the heat input locations and the heat exchanger.

4. The method of claim 1, comprising pumping the flow of liquid with a pump located between the said part of the pipework between the heat input locations and an inlet of the heat exchanger, wherein the pump disrupts the supramolecular aggregates.

5. The method of claim 1, wherein the pipework includes a structure, which is located at or adjacent to and upstream of the heat exchanger and which is shaped to compel the liquid flowing through the structure to undergo extensional flow and thereby disrupt the supramolecular aggregates as the liquid arrives at the heat exchanger.

6. The method of claim 5, wherein the structure at or adjacent to and upstream of the heat exchanger is shaped to reduce the cross-sectional area available for flow and thereby compel the flow to accelerate.

7. The method of claim 6, wherein the structure at or adjacent to and upstream of the heat exchanger is configured to form the flow into a jet directed at a target.

8. The method of claim 1, wherein the compound able to form supramolecular aggregates has a molecular weight not greater than 1000 Daltons.

9. The method of claim 1, wherein the coolant liquid also includes, in solution therein, a polymer which has a molecular weight not greater than 20 kiloDaltons and which has ionic groups in the polymer chain or in side chains attached to the polymer chain.

10. The method of claim 1, wherein the coolant liquid is an emulsion or suspension containing a disperse phase comprising a substance which has a melting temperature above the temperature of coolant liquid returning to the heat input locations and which melts at heat input locations.

11. The method of claim 10, wherein the coolant liquid is an emulsion or suspension in which the said substance has a melting temperature in a range from 25 °C to 60 °C.

12. The method of claim 10, wherein the disperse phase comprises encapsulated particles of a said substance which has a melting temperature above the temperature of coolant liquid returning to the heat input locations and which melts at heat input locations, with the individual particles encapsulated within a polymer shell.

13. A data center heat transfer system comprising:
a heat exchanger comprising one or more internal flow paths from which heat transfers to another system;
pipework, external to the heat exchanger, configured to provide a flow path for coolant liquid from one or more heat inputs receiving heat from computing equipment to the heat exchanger;
a coolant liquid; and
at least one pump for propelling the liquid through the pipework to the heat exchanger, wherein the coolant liquid is an aqueous solution of a compound able to spontaneously form supramolecular aggregates in the coolant liquid;
in at least part of the pipework, the coolant liquid, the pipework dimensions and the pumping rate provide turbulent flow in which supramolecular aggregates reduce drag; and
in at least part of the internal flow paths of the heat exchanger, there is temporary disruption of the supramolecular aggregates and less reduction of drag.

14. The system of claim 13, wherein the said part of the internal flow paths is shaped to subject the flow to greater shear than in the said part of the pipework in which supramolecular aggregates reduce drag.

15. The system of claim 13, wherein the said part of the pipework and the said part of the internal flow paths of the heat exchanger are configured so that the flow velocity in the said part of the internal flow paths is greater than the flow velocity in the said part of the pipework in which supramolecular aggregates reduce drag.

16. The system of claim 13, wherein the flow path to the heat exchanger comprises a component, between the said part of the pipework between the heat input locations and an inlet of the heat exchanger, which is configured to disrupt the supramolecular aggregates.

17. The system of claim 16, wherein the component is a said pump for propelling the liquid through the pipework to the heat exchanger.

18. The system of claim 16, wherein the component is a structure which is located at or adjacent to and upstream of the heat exchanger and which is shaped to reduce the cross-sectional area available for flow and thereby compel the flow to accelerate.

19. The system of claim 16, wherein the component comprises a structure which is located adjacent to and upstream of the heat exchanger and which is shaped to compel the liquid flowing through the structure to undergo extensional flow.

20. The system of claim 19, wherein the component is configured to form the flow into a jet directed at a target.

21. The system of claim 13, wherein the compound able to form supramolecular aggregates has a molecular weight not greater than 1000 Daltons.

22. The system of claim 13, wherein the coolant liquid also includes, in solution therein, a polymer which has a molecular weight not greater than 20 kiloDaltons and which has ionic groups in the polymer chain or in side chains attached to the polymer chain.

23. The system of claim 13, wherein the coolant liquid is an emulsion or suspension containing a disperse phase comprising a substance which has a melting temperature above the temperature of coolant liquid returning to the heat input locations and which melts at heat input locations.

24. The system of claim 23, wherein the coolant liquid is an emulsion or suspension in which the said substance has a melting temperature in a range from 25 °C to 60 °C.

25. The system of claim 23, wherein the disperse phase comprises encapsulated particles of a said substance which has a melting temperature above the temperature of coolant liquid returning to the heat input locations and which melts at heat input locations, with the individual particles encapsulated within a polymer shell.
